(19) United States
(12) Patent Application Publication
(10) Pub. No.: US 2021/0073668 A1
(43) Pub. Date: Mar. 11, 2021

(54) Computer System and Method for Implementing a Conditional Reflection Operator on a Quantum Computer

(71) Applicant: Zapata Computing, Inc., Boston, MA (US)

(72) Inventor: Pierre-Luc Dallaire-Demers, Toronto (CA)

(21) Appl. No.: 17/013,616

(22) Filed: Sep. 6, 2020

Related U.S. Application Data
(60) Provisional application No. 62/896,927, filed on Sep. 6, 2019.

(51) Int. Cl. G06N 10/00; H01L 29/66; H01L 29/423

(52) U.S. Cl. CPC G06N 10/00; H01L 29/423; H01L 29/66977

(57) ABSTRACT

A computer system and method implement a conditional reflection operator on a quantum computer (such as an ion trap quantum computer) with a trap topology containing at least two t-junctions and at least one central interaction zone that can execute Molmer-Sorensen gates on at least two ions.

### CROSS-REFERENCE TO RELATED APPLICATIONS

This application is related to U.S. patent application Ser. No. 16/900,947, filed on Jun. 14, 2020, entitled, “Hybrid Quantum-Classical Computer for Bayesian Inference with Engineered Likelihood,” which is hereby incorporated by reference herein.

### BACKGROUND

The conditional reflection operator is a necessary component of Bayesian operator estimation. In Bayesian operator estimation, the main quantum registers are a system register S composed of n qubits and a single-qubit probe register P. Register S is used to construct a parametrized wave function that represents the solution to an optimization problem of interest in quantum chemistry, material science, machine learning and other fields. Register P is used as an interferometer and measured to estimate a quantity of interest.

### SUMMARY

A computer system and method implement a conditional reflection operator on a quantum computer (such as an ion trap quantum computer) with a trap topology containing at least two t-junctions and at least one central interaction zone that can execute Molmer-Sorensen gates on at least two ions.

### BRIEF DESCRIPTION OF THE DRAWINGS

FIG. 1 is a diagram of a quantum computer according to one embodiment of the present invention;

FIG. 2A is a flowchart of a method performed by the quantum computer of FIG. 1 according to one embodiment of the present invention;

FIG. 2B is a diagram of a hybrid quantum-classical computer which performs quantum annealing according to one embodiment of the present invention;

FIG. 3 is a diagram of a hybrid quantum-classical computer according to one embodiment of the present invention;

FIG. 4 is a diagram of a method performed by an embodiment of the present invention;

FIG. 5 is a diagram of a topology of an ion trap quantum computer implemented according to one embodiment of the present invention;

FIG. 6 is a connectivity diagram of the register S, P, Q and K for an example in which n=8 qubits in the S register;

FIG. 7 illustrates a decomposition of the reflection operator for an example in which n=8 qubits in the S register; and

FIG. 8 illustrates an initial configuration of registers for an example in which n=8 qubits in the S register.

### DETAILED DESCRIPTION

Embodiments of the present invention are directed to computer-implemented systems and methods for performing a conditional reflection operator (CRO) on a quantum computer, such as an ion trap quantum computer.

For example, one embodiment of the present invention is directed to a method for implementing a conditional reflection operator on a quantum computer. The method includes initializing a configuration of qubits according to an operation schedule of generalized Toffoli gates. This operation schedule describes an order of operations to be applied so as to implement the conditional reflection operator. A series of Molmer-Sorenson operations is then applied on a first subset qubits in the configuration according to the operation schedule, resulting in the operation of a first generalized Toffoli gate. Further Molmer-Sorenson operations are applied to other subsets of qubits according to the operation schedule, until the Molmer-Sorenson operations have been applied to all of the qubits in the configuration.

Certain embodiments of the present invention which are implemented on, or in connection with, an ion trap quantum computer will now be described. Embodiments of the present invention are not, however, limited to implementations on, or in connection with, ion trap quantum computers. Embodiments of the present invention may, for example, be implemented on, or in connection with, any universal quantum computer, or any quantum computer capable of performing swap gates and Molmer-Sorensen operations.

In an ion trap quantum computer, a goal is to minimize the amount of shuttling of ions in different zones of an ion trap. Doing so minimizes the amount of quantum coherence required to implement the conditional reflection operator (CRO). In the context of Bayesian operator estimation, this maximizes the amount of quantum coherence dedicated for the construction of the ansatz state.

In some ion trap quantum computers, each qubit is encoded in the hyperfine levels of ions. The ions are held in place by electromagnetic traps. Single qubit operations may be executed with lasers. Each qubit ion is paired with a cooling ion which is used to reset the qubit to its ground state. Multi-qubit gates may be executed in interaction zones, in which ions are put in a state in which they effectively evolve their state jointly through a Molmer-Sorensen interaction.

The electrodes used to generate the electromagnetic trapping potential may be aligned to trap the ions in a linear chain configuration. The junction of two linear trapping potential with the appropriate electrode configuration is called a t-junction. An interaction zone is a line segment in a given trapping potential configuration.

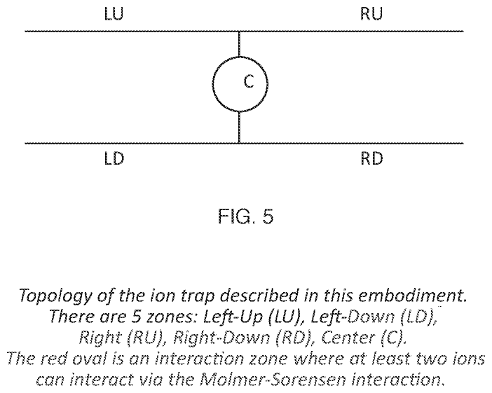

In some embodiments of the present invention, the configuration of the ion trap quantum computer contains at least two t-junctions and at least one central interaction zone. A minimal topology is shown in FIG. 5. It has four zones labeled LU, LD, RU and RD, joined by two t-junctions and a central zone C where at least two ions can interact. There may also be additional interaction zones in LU, LD, RU and RD. The oval is an interaction zone, in which at least two ions may interact via the Molmer-Sorenson interaction.

In this example, denote a single qubit ancilla register Q and an (n−1)-qubit ancilla register K. The qubits in Q and K start and end the protocol for the CRO in the |0 [symbol] state, which means that they may be reused for each execution of the CRO.

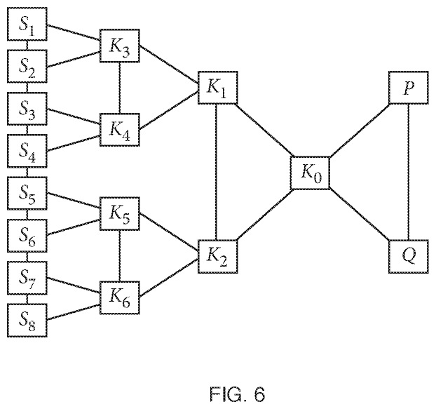

If there are n qubits in register S, we need at least 2n+1 qubits in total. An example of the interaction graph for n=8 is shown in FIG. 6. The black lines between pairs of qubits indicate the presence of a 2-qubit gate.

Denote the j^{th} qubit in register A as Aⱼ. A multi-controlled Toffoli operation with controls on register A with a qubits to register B with 1 qubit can be denoted as c^{A}−X_{B}=c^{A}^{₁}− . . . −c^{A}^{ₐ}−X_{B}. It applies the NOT operation on register B if all qubits in A are in the state |1 [symbol] .

Similarly, denote a conjugate multi-control Toffoli c̅^{A}−X_{B}=X_{A}(c^{A}^{₁}− . . . −c^{A}^{ₐ}−X_{B})X_{A} where X_{A}=Πⱼ₌₁^{a}X_{A} is the parallel application of the NOT operation on all qubits in register A. It applies the NOT operation on register B if all qubits in A are in the state |0 [symbol] .

Bayesian operator estimation generally involves the application of a conditional unitary U^{m}. The 1-qubit register P is measured to estimate the expectation value of an observable of a system encoded in the n-qubit register S. In the register notation we will refer to this conditional unitary as c^{P}−U_{S}^{m}. The reflection operator as used in Bayesian operator estimation is defined as a unitary operator Λ=I−2|0 [symbol] [symbol] 0| which changes the sign of the amplitude of the |0 [symbol] component of an input state. The CRO is the conditional version with a control qubit c−Λ.

To implement c^{P}−U_{S}^{m}, the CRO c^{P}−Π_{S} may be implemented, where Π_{S}=I_{S}−2|0 [symbol] _{S} [symbol] 0|_{S}=−R₀.

Using the qubit Q initialized in the state |0 [symbol] _{Q}, the CRO may be decomposed as c^{P}−Π_{S}=X_{Q}H_{Q}(c^{P}−c̅^{S}−X_{Q})H_{Q}X_{Q}, where X_{Q} and H_{Q} are respectively the single-qubit NOT and Hadamard operations on the qubit of register Q used to prepare (and unprepare) the state |− [symbol] _{Q}=H_{Q}X_{Q}|0 [symbol] Q. If P is in state |1 [symbol] _{P}, it flips the phase of the coefficient associated with the state |0 [symbol] _{S} [symbol] 0|_{S}. The operation returns the state of Q in the |0 [symbol] _{Q} state, which means it may be (reset and) reused for further applications of the c^{P}−Π_{S} gate.

An n−1 qubit register K is added to implement the reflection operator in depth 2┌log₂n┐+1 with respect to the Toffoli (c−c−X) operations.

The qubits in K are labelled from 0 to n−1 and are layered in a binary tree architecture. Qubit K₀ is the root of the tree (for n>1); it may interact with qubits P and Q (which may also interact). A qubit Kⱼ has children K₂ⱼ₊₁ (left) and K₂ⱼ₊₂ (right); all three may interact pairwise. Hence, a qubit Kⱼ has parent qubit

$${K}_{⌊ \frac{j - 1}{2} ⌋} .$$

The qubits of register S may be considered as the leaves of the tree. The parent of qubit Sⱼ is

$${K}_{⌊ \frac{n + j}{2} ⌋ - 1} ,$$

to which it is coupled. Toffoli gates may be implemented on ion trap quantum computers. Starting from the leaves of the tree, Toffoli gates may be applied in parallel from children to parent nodes

$${c}^{{K}_{j}} - {c}^{{K}_{j + 1}} - {X}_{{K}_{⌊ \frac{j - 1}{2} ⌋}} .$$

For the case in which the children control qubits are from the register S (indexed from j=1 to n),

$${\overline{c}}^{{S}_{j}} - {\overline{c}}^{{S}_{j + 1}} - {X}_{{K}_{⌊ \frac{n + j}{2} ⌋ - 1}}$$

may be applied. These operations may be fined tuned with quantum optimal control.

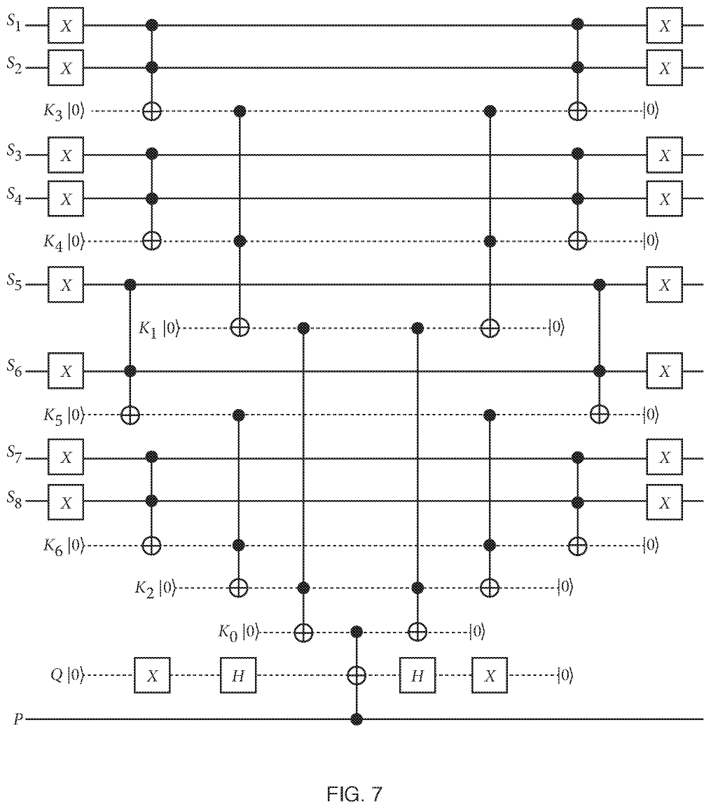

Hence, the operation c^{P}−c̅^{S}−X_{Q} may be performed in depth 2└log₂n┐+1 by first propagating Toffoli operations from the S register to the root K₀, applying X_{Q}H_{Q}(c^{K}^{₀}−c^{P}−X_{Q})H_{Q}X_{Q} and undoing the Toffoli operations on K and S. This leaves the qubits in register K in the state |0 [symbol] _{K}, which may be reused for further rounds of c^{P}−Π_{S}. An example for the decomposition of the CRO is shown in FIG. 7.

To mimic the interaction diagram of FIG. 6 with an ion trap quantum computer, ions may be shuttled between different zones to connect the required qubits. When using only one interaction zone, the CRO may involve the sequential execution of 2n−1 Toffoli gates. This may be improved by using higher-order Toffoli gates (with more than 2 control qubits) and by parallelizing the execution of the Toffoli gates with many interaction zones.

A shuttling and interaction schedule (which is an example of what is referred to herein as an “operation schedule”) which is scalable and allows the implementation of the CRO on an ion trap quantum computer according to embodiments of the present invention is now described.

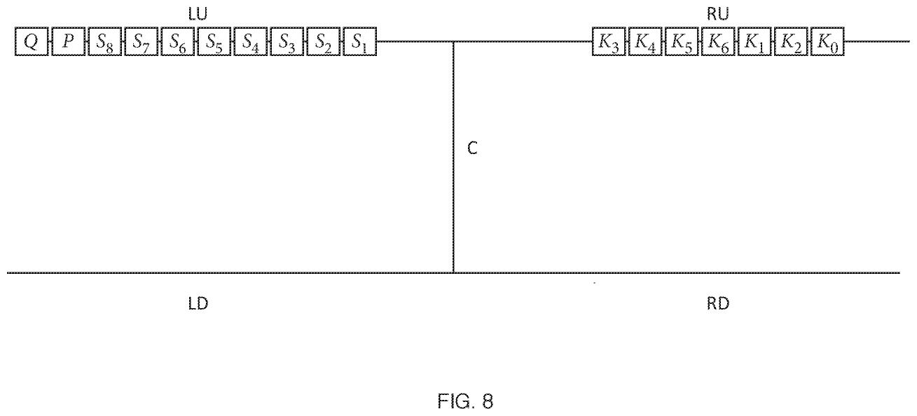

The edge zones LU, LD, RU and RD may be operated as stacks, which means they may be ordered lists of qubits equipped with a function append( ), which adds an element at the end of the list (top of the stack) and a function pop( ), which removes the last element added to the stack. The central zone C is a directional stack, meaning that appendU( ) and appendD( ) respectively add an element to the top (bottom) of the stack and popU( ) and popD( ) removes the top (bottom) element of the stack. Furthermore, C has an interaction zone where Toffoli gates on 3 qubits may be executed. An example of the initial configuration of the trap is shown in FIG. 8.

The protocol may be defined recursively, meaning that the functions involved call themselves. For simplicity in this description, it is assumed that n=2^{G} is a power of 2.

Pseudo-code describing an operation schedule (e.g., a shuttling and interaction schedule) according to one embodiment of the present invention is shown in Table 1.

TABLE 1

```
def move_and_toffoli_forward(r):
  if r > 1:
    $repeat \frac{r}{2} times \text{:}$
      repeat 2 times:
        C.appendU(LU.pop( ))
      C.appendU(RU.pop( ))
      C.toffoli( )
      repeat 2 times:
        LD.append(C.popD( ))
      RD.append(C.popD( ))
    $repeat \frac{r}{2} times \text{:}$
      LU.append(RD.pop( ))
    $move\_and \_toffoli \_forward ( \frac{r}{2} )$
def move_and_toffoli_backward(r):
  if r > 1:
    $move\_and \_toffoli \_backward ( \frac{r}{2} )$
    $repeat \frac{r}{2} times \text{:}$
      RD.append(LU.pop( ))
$repeat \frac{r}{2} times \text{:}$
  C.appendD(RD.pop( ))
  repeat 2 times:
    C.appendD(LD.pop( ))
  C.toffoli( )
  RU.append(C.popU( ))
    repeat 2 times:
      LU.append(C.popU( ))
def reflection_operator(n):
            LU = [Q, P, Sₙ, Sₙ₋₁, . . . , S₁]
            $\begin{matrix}RU = [ {K}_{2} , {K}_{1} , … , {K}_{⌊ \frac{n + 1}{2} ⌋ - 1} , … , {K}_{n - 1} ] \\ LD = [ ] \\ RD = [ ]\end{matrix}$
  apply NOT gate on all qubits in register S
move_and_toffoli_forward(n)
repeat 3 times:
    C.appendU(LU.pop( ))
apply NOT gate on qubit Q
  apply H gate on qubit Q
C.toffoli( )
apply H gate on qubit Q
apply NOT gate on qubit Q
repeat 3 times:
    LU.append(C.popU( ))
move_and_toffoli_backward(n)
apply NOT gate on all qubits in register S
```

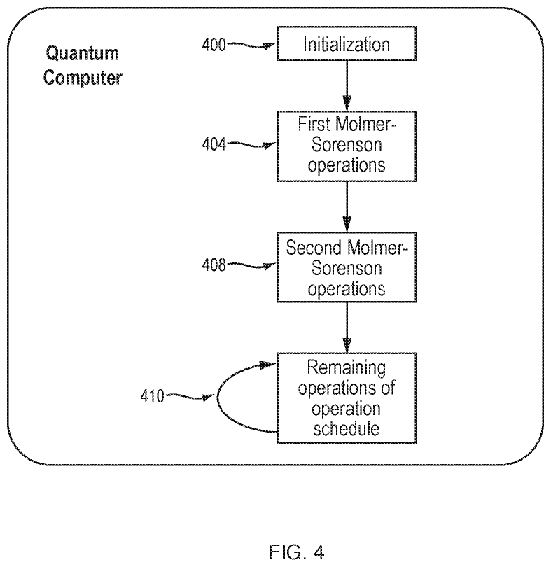

Referring to FIG. 4, a diagram is shown of a method, performed by an embodiment of the present invention, for implementing a conditional reflection operator on a quantum computer. The method may, for example, be performed by the quantum computer or by a hybrid quantum-classical (HQC) computer. The method includes: (A) initializing, on the quantum computer, a configuration of a plurality of qubits according to an operation schedule of generalized Toffoli gates, wherein the plurality of qubits comprises at least three qubits (FIG. 4, operation 400); (B) applying, on the quantum computer, a series of Molmer-Sorenson operations on a first subset of the plurality of qubits in the configuration according to the operation schedule to produce a first generalized Toffoli gate (FIG. 4, operation 404); and (C) applying, on the quantum computer, the series of Molmer-Sorenson operations on a second subset of the plurality of qubits in the configuration according to the operation schedule to produce a second generalized Toffoli gate, wherein the first subset differs from the second subset. The plurality of qubits may include any number of qubits that is at least equal to 3, such as at least 4 qubits, at least 8 qubits, at least 16 qubits, at least 32 qubits, at least 64 qubits, or at least 128 qubits.

The quantum computer may be an ion trap quantum computer, and the initializing may include initializing the configuration of the plurality of qubits by shuttling ions into a two t-junction configuration on the ion trap quantum computer. The method may include, after (B) and before (C), replacing the first subset of the plurality of qubits in the interaction zone by the second subset of the plurality of qubits.

Although the method is described above as being applied to two subsets of the plurality of qubits in the configuration, this is merely an example and not a limitation of the present invention. For example, the method may further include repeating (C) on one or more additional subsets of the plurality of qubits in the configuration until generalized Toffoli gates have been applied to all qubits in the plurality of qubits according to the operation schedule (FIG. 4, operation 410). In other words, the method may be applied to subsets of the plurality of qubits in the configuration until generalized Toffoli gates have been applied to all qubits in the plurality of qubits according to the operation schedule.

The first and second generalized Toffoli gates may be high-order Toffoli gates. Each of the first and second generalized Toffoli gates may include two control qubits.

The method may further include: (D) performing Bayesian operator estimation using the conditional reflection operator.

Applying the series of Molmer-Sorenson operations on the first subset of the plurality of qubits in the configuration may include applying the series of Molmer-Sorenson operations on the first subset of the plurality of qubits in the configuration via a compiled set of quantum gates. Applying the series of Molmer-Sorenson operations on the second subset of the plurality of qubits in the configuration may include applying the series of Molmer-Sorenson operations on the second subset of the plurality of qubits in the configuration via the compiled set of quantum gates.

Another embodiment of the present invention is directed to a system comprising at least one processor and at least one non-transitory computer-readable medium having computer program instructions stored thereon, the computer program instructions being executable by the at least one processor to perform a method for implementing a conditional reflection operator on a quantum computer. The method may include controlling the quantum computer to perform operations of: (A) initializing, on the quantum computer, a configuration of a plurality of qubits according to an operation schedule of generalized Toffoli gates, wherein the plurality of qubits comprises at least three qubits, (B) applying, on the quantum computer, a series of Molmer-Sorenson operations on a first subset of the plurality of qubits in the configuration according to the operation schedule to produce a first generalized Toffoli gate; and (C) applying, on the quantum computer, the series of Molmer-Sorenson operations on a second subset of the plurality of qubits in the configuration according to the operation schedule to produce a second generalized Toffoli gate, wherein the first subset differs from the second subset.

The quantum computer may be an ion trap quantum computer, and the initializing may include initializing the configuration of the plurality of qubits by shuttling ions into a two t-junction configuration on an ion trap quantum computer. The method may further include, after (B) and before (C), replacing the first subset of the plurality of qubits in the interaction zone by the second subset of the plurality of qubits.

The method may further include repeating (C) on additional subsets of the plurality of qubits in the configuration until generalized Toffoli gates have been applied to all qubits in the plurality of qubits according to the operation schedule.

The first and second generalized Toffoli gates may be high-order Toffoli gates. Each of the first and second generalized Toffoli gates may include two control qubits.

The method may further include: (D) performing Bayesian operator estimation using the conditional reflection operator.

Applying the series of Molmer-Sorenson operations on the first subset of the plurality of qubits in the configuration may include applying the series of Molmer-Sorenson operations on the first subset of the plurality of qubits in the configuration via a compiled set of quantum gates. Applying the series of Molmer-Sorenson operations on the second subset of the plurality of qubits in the configuration may include applying the series of Molmer-Sorenson operations on the second subset of the plurality of qubits in the configuration via the compiled set of quantum gates.

The system may further include the quantum computer and/or the classical computer.

It is to be understood that although the invention has been described above in terms of particular embodiments, the foregoing embodiments are provided as illustrative only, and do not limit or define the scope of the invention. Various other embodiments, including but not limited to the following, are also within the scope of the claims. For example, elements and components described herein may be further divided into additional components or joined together to form fewer components for performing the same functions.

Various physical embodiments of a quantum computer are suitable for use according to the present disclosure. In general, the fundamental data storage unit in quantum computing is the quantum bit, or qubit. The qubit is a quantum-computing analog of a classical digital computer system bit. A classical bit is considered to occupy, at any given point in time, one of two possible states corresponding to the binary digits (bits) 0 or 1. By contrast, a qubit is implemented in hardware by a physical medium with quantum-mechanical characteristics. Such a medium, which physically instantiates a qubit, may be referred to herein as a “physical instantiation of a qubit,” a “physical embodiment of a qubit,” a “medium embodying a qubit,” or similar terms, or simply as a “qubit,” for ease of explanation. It should be understood, therefore, that references herein to “qubits” within descriptions of embodiments of the present invention refer to physical media which embody qubits.

Each qubit has an infinite number of different potential quantum-mechanical states. When the state of a qubit is physically measured, the measurement produces one of two different basis states resolved from the state of the qubit. Thus, a single qubit can represent a one, a zero, or any quantum superposition of those two qubit states; a pair of qubits can be in any quantum superposition of 4 orthogonal basis states; and three qubits can be in any superposition of 8 orthogonal basis states. The function that defines the quantum-mechanical states of a qubit is known as its wavefunction. The wavefunction also specifies the probability distribution of outcomes for a given measurement. A qubit, which has a quantum state of dimension two (i.e., has two orthogonal basis states), may be generalized to a d-dimensional “qudit,” where d may be any integral value, such as 2, 3, 4, or higher. In the general case of a qudit, measurement of the qudit produces one of d different basis states resolved from the state of the qudit. Any reference herein to a qubit should be understood to refer more generally to an d-dimensional qudit with any value of d.

Although certain descriptions of qubits herein may describe such qubits in terms of their mathematical properties, each such qubit may be implemented in a physical medium in any of a variety of different ways. Examples of such physical media include superconducting material, trapped ions, photons, optical cavities, individual electrons trapped within quantum dots, point defects in solids (e.g., phosphorus donors in silicon or nitrogen-vacancy centers in diamond), molecules (e.g., alanine, vanadium complexes), or aggregations of any of the foregoing that exhibit qubit behavior, that is, comprising quantum states and transitions therebetween that can be controllably induced or detected.

For any given medium that implements a qubit, any of a variety of properties of that medium may be chosen to implement the qubit. For example, if electrons are chosen to implement qubits, then the x component of its spin degree of freedom may be chosen as the property of such electrons to represent the states of such qubits. Alternatively, the y component, or the z component of the spin degree of freedom may be chosen as the property of such electrons to represent the state of such qubits. This is merely a specific example of the general feature that for any physical medium that is chosen to implement qubits, there may be multiple physical degrees of freedom (e.g., the x, y, and z components in the electron spin example) that may be chosen to represent 0 and 1. For any particular degree of freedom, the physical medium may controllably be put in a state of superposition, and measurements may then be taken in the chosen degree of freedom to obtain readouts of qubit values.

Certain implementations of quantum computers, referred as gate model quantum computers, comprise quantum gates. In contrast to classical gates, there is an infinite number of possible single-qubit quantum gates that change the state vector of a qubit. Changing the state of a qubit state vector typically is referred to as a single-qubit rotation, and may also be referred to herein as a state change or a single-qubit quantum-gate operation. A rotation, state change, or single-qubit quantum-gate operation may be represented mathematically by a unitary 2×2 matrix with complex elements. A rotation corresponds to a rotation of a qubit state within its Hilbert space, which may be conceptualized as a rotation of the Bloch sphere. (As is well-known to those having ordinary skill in the art, the Bloch sphere is a geometrical representation of the space of pure states of a qubit.) Multi-qubit gates alter the quantum state of a set of qubits. For example, two-qubit gates rotate the state of two qubits as a rotation in the four-dimensional Hilbert space of the two qubits. (As is well-known to those having ordinary skill in the art, a Hilbert space is an abstract vector space possessing the structure of an inner product that allows length and angle to be measured. Furthermore, Hilbert spaces are complete: there are enough limits in the space to allow the techniques of calculus to be used.)

A quantum circuit may be specified as a sequence of quantum gates. As described in more detail below, the term “quantum gate,” as used herein, refers to the application of a gate control signal (defined below) to one or more qubits to cause those qubits to undergo certain physical transformations and thereby to implement a logical gate operation. To conceptualize a quantum circuit, the matrices corresponding to the component quantum gates may be multiplied together in the order specified by the gate sequence to produce a 2nX2n complex matrix representing the same overall state change on n qubits. A quantum circuit may thus be expressed as a single resultant operator. However, designing a quantum circuit in terms of constituent gates allows the design to conform to a standard set of gates, and thus enable greater ease of deployment. A quantum circuit thus corresponds to a design for actions taken upon the physical components of a quantum computer.

A given variational quantum circuit may be parameterized in a suitable device-specific manner. More generally, the quantum gates making up a quantum circuit may have an associated plurality of tuning parameters. For example, in embodiments based on optical switching, tuning parameters may correspond to the angles of individual optical elements.

In certain embodiments of quantum circuits, the quantum circuit includes both one or more gates and one or more measurement operations. Quantum computers implemented using such quantum circuits are referred to herein as implementing “measurement feedback.” For example, a quantum computer implementing measurement feedback may execute the gates in a quantum circuit and then measure only a subset (i.e., fewer than all) of the qubits in the quantum computer, and then decide which gate(s) to execute next based on the outcome(s) of the measurement(s). In particular, the measurement(s) may indicate a degree of error in the gate operation(s), and the quantum computer may decide which gate(s) to execute next based on the degree of error. The quantum computer may then execute the gate(s) indicated by the decision. This process of executing gates, measuring a subset of the qubits, and then deciding which gate(s) to execute next may be repeated any number of times. Measurement feedback may be useful for performing quantum error correction, but is not limited to use in performing quantum error correction. For every quantum circuit, there is an error-corrected implementation of the circuit with or without measurement feedback.

Some embodiments described herein generate, measure, or utilize quantum states that approximate a target quantum state (e.g., a ground state of a Hamiltonian). As will be appreciated by those trained in the art, there are many ways to quantify how well a first quantum state “approximates” a second quantum state. In the following description, any concept or definition of approximation known in the art may be used without departing from the scope hereof. For example, when the first and second quantum states are represented as first and second vectors, respectively, the first quantum state approximates the second quantum state when an inner product between the first and second vectors (called the “fidelity” between the two quantum states) is greater than a predefined amount (typically labeled c). In this example, the fidelity quantifies how “close” or “similar” the first and second quantum states are to each other. The fidelity represents a probability that a measurement of the first quantum state will give the same result as if the measurement were performed on the second quantum state. Proximity between quantum states can also be quantified with a distance measure, such as a Euclidean norm, a Hamming distance, or another type of norm known in the art. Proximity between quantum states can also be defined in computational terms. For example, the first quantum state approximates the second quantum state when a polynomial time-sampling of the first quantum state gives some desired information or property that it shares with the second quantum state.

Not all quantum computers are gate model quantum computers. Embodiments of the present invention are not limited to being implemented using gate model quantum computers. As an alternative example, embodiments of the present invention may be implemented, in whole or in part, using a quantum computer that is implemented using a quantum annealing architecture, which is an alternative to the gate model quantum computing architecture. More specifically, quantum annealing (QA) is a metaheuristic for finding the global minimum of a given objective function over a given set of candidate solutions (candidate states), by a process using quantum fluctuations.

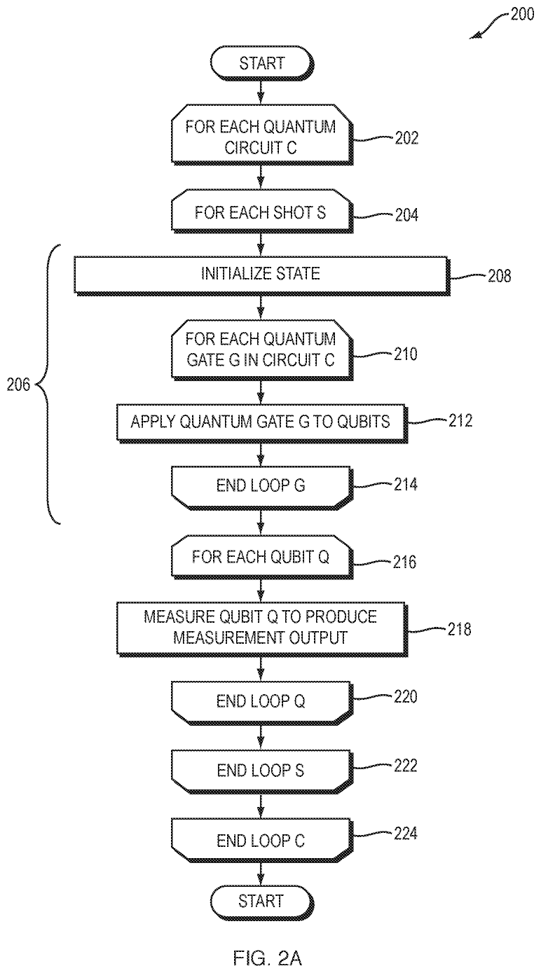

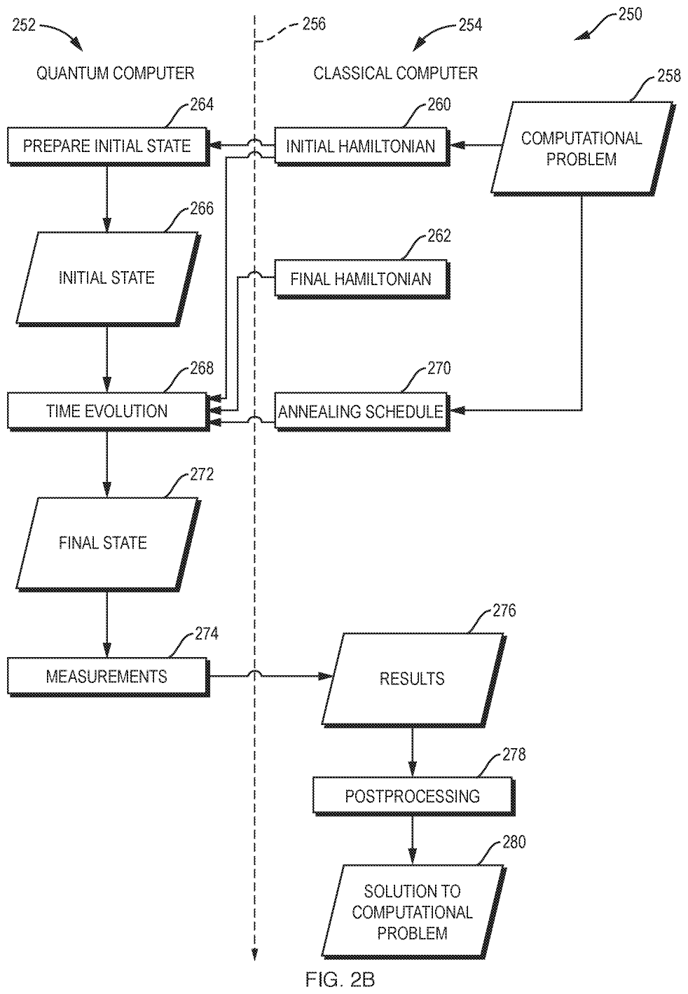

FIG. 2B shows a diagram illustrating operations typically performed by a computer system 250 which implements quantum annealing. The system 250 includes both a quantum computer 252 and a classical computer 254. Operations shown on the left of the dashed vertical line 256 typically are performed by the quantum computer 252, while operations shown on the right of the dashed vertical line 256 typically are performed by the classical computer 254.

Quantum annealing starts with the classical computer 254 generating an initial Hamiltonian 260 and a final Hamiltonian 262 based on a computational problem 258 to be solved, and providing the initial Hamiltonian 260, the final Hamiltonian 262 and an annealing schedule 270 as input to the quantum computer 252. The quantum computer 252 prepares a well-known initial state 266 (FIG. 2B, operation 264), such as a quantum-mechanical superposition of all possible states (candidate states) with equal weights, based on the initial Hamiltonian 260. The classical computer 254 provides the initial Hamiltonian 260, a final Hamiltonian 262, and an annealing schedule 270 to the quantum computer 252. The quantum computer 252 starts in the initial state 266, and evolves its state according to the annealing schedule 270 following the time-dependent Schrödinger equation, a natural quantum-mechanical evolution of physical systems (FIG. 2B, operation 268). More specifically, the state of the quantum computer 252 undergoes time evolution under a time-dependent Hamiltonian, which starts from the initial Hamiltonian 260 and terminates at the final Hamiltonian 262. If the rate of change of the system Hamiltonian is slow enough, the system stays close to the ground state of the instantaneous Hamiltonian. If the rate of change of the system Hamiltonian is accelerated, the system may leave the ground state temporarily but produce a higher likelihood of concluding in the ground state of the final problem Hamiltonian, i.e., diabatic quantum computation. At the end of the time evolution, the set of qubits on the quantum annealer is in a final state 272, which is expected to be close to the ground state of the classical Ising model that corresponds to the solution to the original optimization problem 258. An experimental demonstration of the success of quantum annealing for random magnets was reported immediately after the initial theoretical proposal.

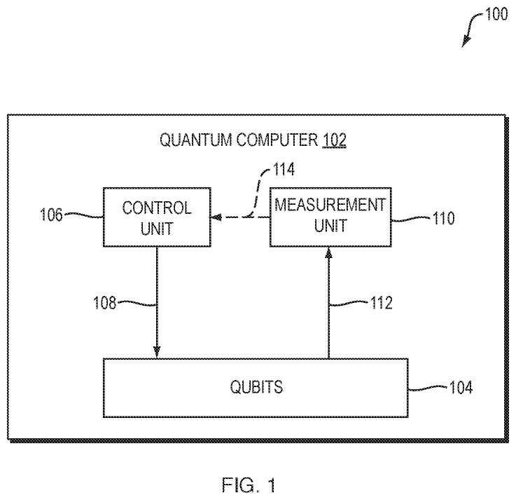

The final state 272 of the quantum computer 254 is measured, thereby producing results 276 (i.e., measurements) (FIG. 2B, operation 274). The measurement operation 274 may be performed, for example, in any of the ways disclosed herein, such as in any of the ways disclosed herein in connection with the measurement unit 110 in FIG. 1. The classical computer 254 performs postprocessing on the measurement results 276 to produce output 280 representing a solution to the original computational problem 258 (FIG. 2B, operation 278).

As yet another alternative example, embodiments of the present invention may be implemented, in whole or in part, using a quantum computer that is implemented using a one-way quantum computing architecture, also referred to as a measurement-based quantum computing architecture, which is another alternative to the gate model quantum computing architecture. More specifically, the one-way or measurement based quantum computer (MBQC) is a method of quantum computing that first prepares an entangled resource state, usually a cluster state or graph state, then performs single qubit measurements on it. It is “one-way” because the resource state is destroyed by the measurements.

The outcome of each individual measurement is random, but they are related in such a way that the computation always succeeds. In general the choices of basis for later measurements need to depend on the results of earlier measurements, and hence the measurements cannot all be performed at the same time.

Any of the functions disclosed herein may be implemented using means for performing those functions. Such means include, but are not limited to, any of the components disclosed herein, such as the computer-related components described below.

Referring to FIG. 1, a diagram is shown of a system 100 implemented according to one embodiment of the present invention. Referring to FIG. 2A, a flowchart is shown of a method 200 performed by the system 100 of FIG. 1 according to one embodiment of the present invention. The system 100 includes a quantum computer 102. The quantum computer 102 includes a plurality of qubits 104, which may be implemented in any of the ways disclosed herein. There may be any number of qubits 104 in the quantum computer 104. For example, the qubits 104 may include or consist of no more than 2 qubits, no more than 4 qubits, no more than 8 qubits, no more than 16 qubits, no more than 32 qubits, no more than 64 qubits, no more than 128 qubits, no more than 256 qubits, no more than 512 qubits, no more than 1024 qubits, no more than 2048 qubits, no more than 4096 qubits, or no more than 8192 qubits. These are merely examples, in practice there may be any number of qubits 104 in the quantum computer 102.

There may be any number of gates in a quantum circuit. However, in some embodiments the number of gates may be at least proportional to the number of qubits 104 in the quantum computer 102. In some embodiments the gate depth may be no greater than the number of qubits 104 in the quantum computer 102, or no greater than some linear multiple of the number of qubits 104 in the quantum computer 102 (e.g., 2, 3, 4, 5, 6, or 7).

The qubits 104 may be interconnected in any graph pattern. For example, they be connected in a linear chain, a two-dimensional grid, an all-to-all connection, any combination thereof, or any subgraph of any of the preceding.

As will become clear from the description below, although element 102 is referred to herein as a “quantum computer,” this does not imply that all components of the quantum computer 102 leverage quantum phenomena. One or more components of the quantum computer 102 may, for example, be classical (i.e., non-quantum components) components which do not leverage quantum phenomena.

The quantum computer 102 includes a control unit 106, which may include any of a variety of circuitry and/or other machinery for performing the functions disclosed herein. The control unit 106 may, for example, consist entirely of classical components. The control unit 106 generates and provides as output one or more control signals 108 to the qubits 104. The control signals 108 may take any of a variety of forms, such as any kind of electromagnetic signals, such as electrical signals, magnetic signals, optical signals (e.g., laser pulses), or any combination thereof.

For example:
In embodiments in which some or all of the qubits 104 are implemented as photons (also referred to as a “quantum optical” implementation) that travel along waveguides, the control unit 106 may be a beam splitter (e.g., a heater or a mirror), the control signals 108 may be signals that control the heater or the rotation of the mirror, the measurement unit 110 may be a photodetector, and the measurement signals 112 may be photons.
In embodiments in which some or all of the qubits 104 are implemented as charge type qubits (e.g., transmon, X-mon, G-mon) or flux-type qubits (e.g., flux qubits, capacitively shunted flux qubits) (also referred to as a “circuit quantum electrodynamic” (circuit QED) implementation), the control unit 106 may be a bus resonator activated by a drive, the control signals 108 may be cavity modes, the measurement unit 110 may be a second resonator (e.g., a low-Q resonator), and the measurement signals 112 may be voltages measured from the second resonator using dispersive readout techniques.
In embodiments in which some or all of the qubits 104 are implemented as superconducting circuits, the control unit 106 may be a circuit QED-assisted control unit or a direct capacitive coupling control unit or an inductive capacitive coupling control unit, the control signals 108 may be cavity modes, the measurement unit 110 may be a second resonator (e.g., a low-Q resonator), and the measurement signals 112 may be voltages measured from the second resonator using dispersive readout techniques.
In embodiments in which some or all of the qubits 104 are implemented as trapped ions (e.g., electronic states of, e.g., magnesium ions), the control unit 106 may be a laser, the control signals 108 may be laser pulses, the measurement unit 110 may be a laser and either a CCD or a photodetector (e.g., a photomultiplier tube), and the measurement signals 112 may be photons.
In embodiments in which some or all of the qubits 104 are implemented using nuclear magnetic resonance (NMR) (in which case the qubits may be molecules, e.g., in liquid or solid form), the control unit 106 may be a radio frequency (RF) antenna, the control signals 108 may be RF fields emitted by the RF antenna, the measurement unit 110 may be another RF antenna, and the measurement signals 112 may be RF fields measured by the second RF antenna.
In embodiments in which some or all of the qubits 104 are implemented as nitrogen-vacancy centers (NV centers), the control unit 106 may, for example, be a laser, a microwave antenna, or a coil, the control signals 108 may be visible light, a microwave signal, or a constant electromagnetic field, the measurement unit 110 may be a photodetector, and the measurement signals 112 may be photons.
In embodiments in which some or all of the qubits 104 are implemented as two-dimensional quasiparticles called “anyons” (also referred to as a “topological quantum computer” implementation), the control unit 106 may be nanowires, the control signals 108 may be local electrical fields or microwave pulses, the measurement unit 110 may be superconducting circuits, and the measurement signals 112 may be voltages.
In embodiments in which some or all of the qubits 104 are implemented as semiconducting material (e.g., nanowires), the control unit 106 may be microfabricated gates, the control signals 108 may be RF or microwave signals, the measurement unit 110 may be microfabricated gates, and the measurement signals 112 may be RF or microwave signals.

Although not shown explicitly in FIG. 1 and not required, the measurement unit 110 may provide one or more feedback signals 114 to the control unit 106 based on the measurement signals 112. For example, quantum computers referred to as “one-way quantum computers” or “measurement-based quantum computers” utilize such feedback 114 from the measurement unit 110 to the control unit 106. Such feedback 114 is also necessary for the operation of fault-tolerant quantum computing and error correction.

The control signals 108 may, for example, include one or more state preparation signals which, when received by the qubits 104, cause some or all of the qubits 104 to change their states. Such state preparation signals constitute a quantum circuit also referred to as an “ansatz circuit.” The resulting state of the qubits 104 is referred to herein as an “initial state” or an “ansatz state.” The process of outputting the state preparation signal(s) to cause the qubits 104 to be in their initial state is referred to herein as “state preparation” (FIG. 2A, section 206). A special case of state preparation is “initialization,” also referred to as a “reset operation,” in which the initial state is one in which some or all of the qubits 104 are in the “zero” state i.e. the default single-qubit state. More generally, state preparation may involve using the state preparation signals to cause some or all of the qubits 104 to be in any distribution of desired states. In some embodiments, the control unit 106 may first perform initialization on the qubits 104 and then perform preparation on the qubits 104, by first outputting a first set of state preparation signals to initialize the qubits 104, and by then outputting a second set of state preparation signals to put the qubits 104 partially or entirely into non-zero states.

Another example of control signals 108 that may be output by the control unit 106 and received by the qubits 104 are gate control signals. The control unit 106 may output such gate control signals, thereby applying one or more gates to the qubits 104. Applying a gate to one or more qubits causes the set of qubits to undergo a physical state change which embodies a corresponding logical gate operation (e.g., single-qubit rotation, two-qubit entangling gate or multi-qubit operation) specified by the received gate control signal. As this implies, in response to receiving the gate control signals, the qubits 104 undergo physical transformations which cause the qubits 104 to change state in such a way that the states of the qubits 104, when measured (see below), represent the results of performing logical gate operations specified by the gate control signals. The term “quantum gate,” as used herein, refers to the application of a gate control signal to one or more qubits to cause those qubits to undergo the physical transformations described above and thereby to implement a logical gate operation.

It should be understood that the dividing line between state preparation (and the corresponding state preparation signals) and the application of gates (and the corresponding gate control signals) may be chosen arbitrarily. For example, some or all the components and operations that are illustrated in FIGS. 1 and 2A-2B as elements of “state preparation” may instead be characterized as elements of gate application. Conversely, for example, some or all of the components and operations that are illustrated in FIGS. 1 and 2A-2B as elements of “gate application” may instead be characterized as elements of state preparation. As one particular example, the system and method of FIGS. 1 and 2A-2B may be characterized as solely performing state preparation followed by measurement, without any gate application, where the elements that are described herein as being part of gate application are instead considered to be part of state preparation. Conversely, for example, the system and method of FIGS. 1 and 2A-2B may be characterized as solely performing gate application followed by measurement, without any state preparation, and where the elements that are described herein as being part of state preparation are instead considered to be part of gate application.

The quantum computer 102 also includes a measurement unit 110, which performs one or more measurement operations on the qubits 104 to read out measurement signals 112 (also referred to herein as “measurement results”) from the qubits 104, where the measurement results 112 are signals representing the states of some or all of the qubits 104. In practice, the control unit 106 and the measurement unit 110 may be entirely distinct from each other, or contain some components in common with each other, or be implemented using a single unit (i.e., a single unit may implement both the control unit 106 and the measurement unit 110). For example, a laser unit may be used both to generate the control signals 108 and to provide stimulus (e.g., one or more laser beams) to the qubits 104 to cause the measurement signals 112 to be generated.

In general, the quantum computer 102 may perform various operations described above any number of times. For example, the control unit 106 may generate one or more control signals 108, thereby causing the qubits 104 to perform one or more quantum gate operations. The measurement unit 110 may then perform one or more measurement operations on the qubits 104 to read out a set of one or more measurement signals 112. The measurement unit 110 may repeat such measurement operations on the qubits 104 before the control unit 106 generates additional control signals 108, thereby causing the measurement unit 110 to read out additional measurement signals 112 resulting from the same gate operations that were performed before reading out the previous measurement signals 112. The measurement unit 110 may repeat this process any number of times to generate any number of measurement signals 112 corresponding to the same gate operations. The quantum computer 102 may then aggregate such multiple measurements of the same gate operations in any of a variety of ways.

After the measurement unit 110 has performed one or more measurement operations on the qubits 104 after they have performed one set of gate operations, the control unit 106 may generate one or more additional control signals 108, which may differ from the previous control signals 108, thereby causing the qubits 104 to perform one or more additional quantum gate operations, which may differ from the previous set of quantum gate operations. The process described above may then be repeated, with the measurement unit 110 performing one or more measurement operations on the qubits 104 in their new states (resulting from the most recently-performed gate operations).

In general, the system 100 may implement a plurality of quantum circuits as follows. For each quantum circuit C in the plurality of quantum circuits (FIG. 2A, operation 202), the system 100 performs a plurality of “shots” on the qubits 104. The meaning of a shot will become clear from the description that follows. For each shot S in the plurality of shots (FIG. 2A, operation 204), the system 100 prepares the state of the qubits 104 (FIG. 2A, section 206). More specifically, for each quantum gate G in quantum circuit C (FIG. 2A, operation 210), the system 100 applies quantum gate G to the qubits 104 (FIG. 2A, operations 212 and 214).

Then, for each of the qubits Q 104 (FIG. 2A, operation 216), the system 100 measures the qubit Q to produce measurement output representing a current state of qubit Q (FIG. 2A, operations 218 and 220).

The operations described above are repeated for each shot S (FIG. 2A, operation 222), and circuit C (FIG. 2A, operation 224). As the description above implies, a single “shot” involves preparing the state of the qubits 104 and applying all of the quantum gates in a circuit to the qubits 104 and then measuring the states of the qubits 104; and the system 100 may perform multiple shots for one or more circuits.

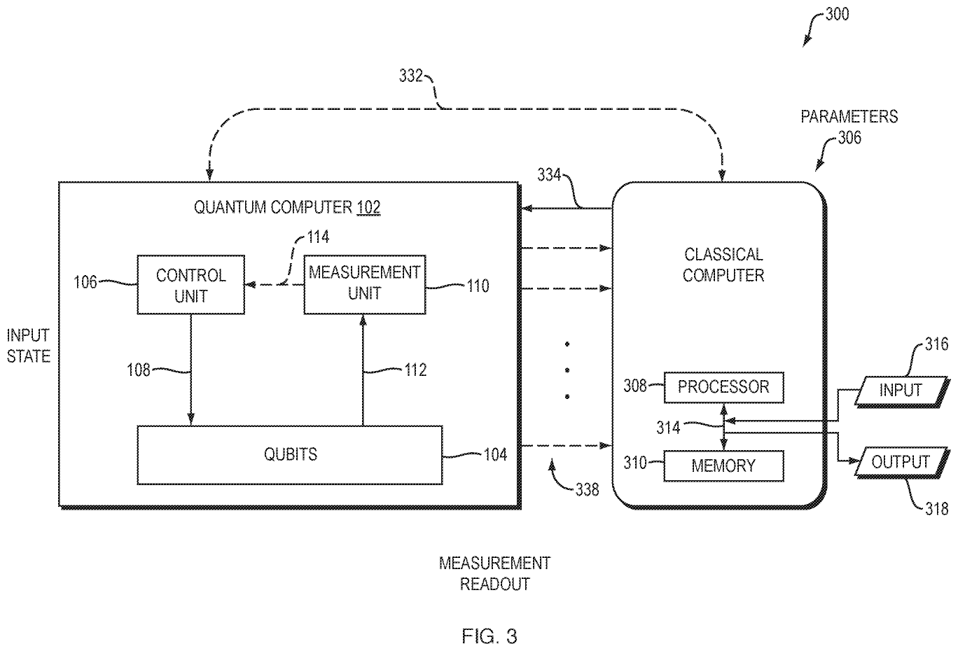

Referring to FIG. 3, a diagram is shown of a hybrid classical quantum computer (HQC) 300 implemented according to one embodiment of the present invention. The HQC 300 includes a quantum computer component 102 (which may, for example, be implemented in the manner shown and described in connection with FIG. 1) and a classical computer component 306. The classical computer component may be a machine implemented according to the general computing model established by John Von Neumann, in which programs are written in the form of ordered lists of instructions and stored within a classical (e.g., digital) memory 310 and executed by a classical (e.g., digital) processor 308 of the classical computer. The memory 310 is classical in the sense that it stores data in a storage medium in the form of bits, which have a single definite binary state at any point in time. The bits stored in the memory 310 may, for example, represent a computer program. The classical computer component 304 typically includes a bus 314. The processor 308 may read bits from and write bits to the memory 310 over the bus 314. For example, the processor 308 may read instructions from the computer program in the memory 310, and may optionally receive input data 316 from a source external to the computer 302, such as from a user input device such as a mouse, keyboard, or any other input device. The processor 308 may use instructions that have been read from the memory 310 to perform computations on data read from the memory 310 and/or the input 316, and generate output from those instructions. The processor 308 may store that output back into the memory 310 and/or provide the output externally as output data 318 via an output device, such as a monitor, speaker, or network device.

The quantum computer component 102 may include a plurality of qubits 104, as described above in connection with FIG. 1. A single qubit may represent a one, a zero, or any quantum superposition of those two qubit states. The classical computer component 304 may provide classical state preparation signals Y32 to the quantum computer 102, in response to which the quantum computer 102 may prepare the states of the qubits 104 in any of the ways disclosed herein, such as in any of the ways disclosed in connection with FIGS. 1 and 2A-2B.

Once the qubits 104 have been prepared, the classical processor 308 may provide classical control signals Y34 to the quantum computer 102, in response to which the quantum computer 102 may apply the gate operations specified by the control signals Y32 to the qubits 104, as a result of which the qubits 104 arrive at a final state. The measurement unit 110 in the quantum computer 102 (which may be implemented as described above in connection with FIGS. 1 and 2A-2B) may measure the states of the qubits 104 and produce measurement output Y38 representing the collapse of the states of the qubits 104 into one of their eigenstates. As a result, the measurement output Y38 includes or consists of bits and therefore represents a classical state. The quantum computer 102 provides the measurement output Y38 to the classical processor 308. The classical processor 308 may store data representing the measurement output Y38 and/or data derived therefrom in the classical memory 310.

The steps described above may be repeated any number of times, with what is described above as the final state of the qubits 104 serving as the initial state of the next iteration. In this way, the classical computer 304 and the quantum computer 102 may cooperate as co-processors to perform joint computations as a single computer system.

Although certain functions may be described herein as being performed by a classical computer and other functions may be described herein as being performed by a quantum computer, these are merely examples and do not constitute limitations of the present invention. A subset of the functions which are disclosed herein as being performed by a quantum computer may instead be performed by a classical computer. For example, a classical computer may execute functionality for emulating a quantum computer and provide a subset of the functionality described herein, albeit with functionality limited by the exponential scaling of the simulation. Functions which are disclosed herein as being performed by a classical computer may instead be performed by a quantum computer.

The techniques described above may be implemented, for example, in hardware, in one or more computer programs tangibly stored on one or more computer-readable media, firmware, or any combination thereof, such as solely on a quantum computer, solely on a classical computer, or on a hybrid classical quantum (HQC) computer. The techniques disclosed herein may, for example, be implemented solely on a classical computer, in which the classical computer emulates the quantum computer functions disclosed herein.

The techniques described above may be implemented in one or more computer programs executing on (or executable by) a programmable computer (such as a classical computer, a quantum computer, or an HQC) including any combination of any number of the following: a processor, a storage medium readable and/or writable by the processor (including, for example, volatile and non-volatile memory and/or storage elements), an input device, and an output device. Program code may be applied to input entered using the input device to perform the functions described and to generate output using the output device.

Embodiments of the present invention include features which are only possible and/or feasible to implement with the use of one or more computers, computer processors, and/or other elements of a computer system. Such features are either impossible or impractical to implement mentally and/or manually. For example, embodiments of the present invention initial configurations of qubits on a quantum computer and apply Molmer-Sorenson operations on those qubits on the quantum computer. Such features are impossible or impractical to implement mentally or manually.

Any claims herein which affirmatively require a computer, a processor, a memory, or similar computer-related elements, are intended to require such elements, and should not be interpreted as if such elements are not present in or required by such claims. Such claims are not intended, and should not be interpreted, to cover methods and/or systems which lack the recited computer-related elements. For example, any method claim herein which recites that the claimed method is performed by a computer, a processor, a memory, and/or similar computer-related element, is intended to, and should only be interpreted to, encompass methods which are performed by the recited computer-related element(s). Such a method claim should not be interpreted, for example, to encompass a method that is performed mentally or by hand (e.g., using pencil and paper). Similarly, any product claim herein which recites that the claimed product includes a computer, a processor, a memory, and/or similar computer-related element, is intended to, and should only be interpreted to, encompass products which include the recited computer-related element(s). Such a product claim should not be interpreted, for example, to encompass a product that does not include the recited computer-related element(s).

In embodiments in which a classical computing component executes a computer program providing any subset of the functionality within the scope of the claims below, the computer program may be implemented in any programming language, such as assembly language, machine language, a high-level procedural programming language, or an object-oriented programming language. The programming language may, for example, be a compiled or interpreted programming language.

Each such computer program may be implemented in a computer program product tangibly embodied in a machine-readable storage device for execution by a computer processor, which may be either a classical processor or a quantum processor. Method steps of the invention may be performed by one or more computer processors executing a program tangibly embodied on a computer-readable medium to perform functions of the invention by operating on input and generating output. Suitable processors include, by way of example, both general and special purpose microprocessors. Generally, the processor receives (reads) instructions and data from a memory (such as a read-only memory and/or a random access memory) and writes (stores) instructions and data to the memory. Storage devices suitable for tangibly embodying computer program instructions and data include, for example, all forms of non-volatile memory, such as semiconductor memory devices, including EPROM, EEPROM, and flash memory devices; magnetic disks such as internal hard disks and removable disks; magneto-optical disks; and CD-ROMs. Any of the foregoing may be supplemented by, or incorporated in, specially-designed ASICs (application-specific integrated circuits) or FPGAs (Field-Programmable Gate Arrays). A classical computer can generally also receive (read) programs and data from, and write (store) programs and data to, a non-transitory computer-readable storage medium such as an internal disk (not shown) or a removable disk. These elements will also be found in a conventional desktop or workstation computer as well as other computers suitable for executing computer programs implementing the methods described herein, which may be used in conjunction with any digital print engine or marking engine, display monitor, or other raster output device capable of producing color or gray scale pixels on paper, film, display screen, or other output medium.

Any data disclosed herein may be implemented, for example, in one or more data structures tangibly stored on a non-transitory computer-readable medium (such as a classical computer-readable medium, a quantum computer-readable medium, or an HQC computer-readable medium). Embodiments of the invention may store such data in such data structure(s) and read such data from such data structure(s).

What is claimed is:

1. A method for implementing a conditional reflection operator on a quantum computer, the method comprising:
(A) initializing, on the quantum computer, a configuration of a plurality of qubits according to an operation schedule of generalized Toffoli gates, wherein the plurality of qubits comprises at least three qubits,
(B) applying, on the quantum computer, a series of Molmer-Sorenson operations on a first subset of the plurality of qubits in the configuration according to the operation schedule to produce a first generalized Toffoli gate;
(C) applying, on the quantum computer, the series of Molmer-Sorenson operations on a second subset of the plurality of qubits in the configuration according to the operation schedule to produce a second generalized Toffoli gate, wherein the first subset differs from the second subset.

2. The method of claim 1, wherein the initializing comprises initializing the configuration of the plurality of qubits by shuttling ions into a two t-junction configuration on an ion trap quantum computer.

3. The method of claim 2, further comprising, after (B) and before (C), replacing the first subset of the plurality of qubits in the interaction zone by the second subset of the plurality of qubits.

4. The method of claim 1, further comprising repeating (C) on additional subsets of the plurality of qubits in the configuration until generalized Toffoli gates have been applied to all qubits in the plurality of qubits according to the operation schedule.

5. The method of claim 1, wherein the first and second generalized Toffoli gates comprise high-order Toffoli gates.

6. The method of claim 1, wherein each of the first and second generalized Toffoli gates includes two control qubits.

7. The method of claim 1, further comprising:
(D) performing Bayesian operator estimation using the conditional reflection operator.

8. The method of claim 1, wherein applying the series of Molmer-Sorenson operations on the first subset of the plurality of qubits in the configuration comprises applying the series of Molmer-Sorenson operations on the first subset of the plurality of qubits in the configuration via a compiled set of quantum gates.

9. The method of claim 8, wherein applying the series of Molmer-Sorenson operations on the second subset of the plurality of qubits in the configuration comprises applying the series of Molmer-Sorenson operations on the second subset of the plurality of qubits in the configuration via the compiled set of quantum gates.

10. A system comprising at least one processor and at least one non-transitory computer-readable medium having computer program instructions stored thereon, the computer program instructions being executable by the at least one processor to perform a method for implementing a conditional reflection operator on a quantum computer, the method comprising controlling the quantum computer to perform operations of:
(A) initializing, on the quantum computer, a configuration of a plurality of qubits according to an operation schedule of generalized Toffoli gates, wherein the plurality of qubits comprises at least three qubits,
(B) applying, on the quantum computer, a series of Molmer-Sorenson operations on a first subset of the plurality of qubits in the configuration according to the operation schedule to produce a first generalized Toffoli gate;
(C) applying, on the quantum computer, the series of Molmer-Sorenson operations on a second subset of the plurality of qubits in the configuration according to the operation schedule to produce a second generalized Toffoli gate, wherein the first subset differs from the second subset.

11. The system of claim 10, wherein the initializing comprises initializing the configuration of the plurality of qubits by shuttling ions into a two t-junction configuration on an ion trap quantum computer.

12. The system of claim 11, wherein the method further comprises, after (B) and before (C), replacing the first subset of the plurality of qubits in the interaction zone by the second subset of the plurality of qubits.

13. The system of claim 10, wherein the method further comprises repeating (C) on additional subsets of the plurality of qubits in the configuration until generalized Toffoli gates have been applied to all qubits in the plurality of qubits according to the operation schedule.

14. The system of claim 10, wherein the first and second generalized Toffoli gates comprise high-order Toffoli gates.

15. The system of claim 10, wherein each of the first and second generalized Toffoli gates includes two control qubits.

16. The system of claim 10, wherein the method further comprises:
(D) performing Bayesian operator estimation using the conditional reflection operator.

17. The system of claim 10, wherein applying the series of Molmer-Sorenson operations on the first subset of the plurality of qubits in the configuration comprises applying the series of Molmer-Sorenson operations on the first subset of the plurality of qubits in the configuration via a compiled set of quantum gates.

18. The system of claim 17, wherein applying the series of Molmer-Sorenson operations on the second subset of the plurality of qubits in the configuration comprises applying the series of Molmer-Sorenson operations on the second subset of the plurality of qubits in the configuration via the compiled set of quantum gates.

19. The system of claim 10, further comprising the quantum computer.

20. The system of claim 19, further comprising the classical computer.
